(19) United States
(12) Patent Application Publication
(10) Pub. No.: US 2024/0276887 A1
(43) Pub. Date: Aug. 15, 2024

(54) DEVICE

(71) Applicant: TDK Electronics AG, München (DE)

(72) Inventors: Wolfgang Wallnöfer, Deutschlandsberg (AT); Jockum Lönnberg, Deutschlandsberg (AT); Johannes Burger, Kirchlauter (DE)

(21) Appl. No.: 18/563,731

(22) PCT Filed: May 13, 2022
(86) PCT No.: PCT/EP2022/063009

§ 371 Date: Nov. 22, 2023

(30) Foreign Application Priority Data
May 28, 2021 (DE) 102021113843.4

(51) Int. Cl. H10N 30/88; G01L 1/16; H10N 30/20; H10N 30/30; H10N 30/50

(52) U.S. Cl. CPC H10N 30/883; G01L 1/16; H10N 30/206; H10N 30/302; H10N 30/501

(57) ABSTRACT

In an embodiment a device includes a piezoelectric multilayer element having a top surface and being configured to change its extension in a first direction in response to an applied voltage, a mechanical amplifying element having an end portion fixed to the top surface of the piezoelectric multilayer element and an active portion movable relative to the piezoelectric multilayer element, wherein the mechanical amplifying element is configured such that the active portion is movable in a second direction perpendicular to the first direction when an extension of the piezoelectric multilayer element changes, the second direction being parallel to a surface normal of the top surface and a mechanical stop limiting a distance by which the active portion is movable towards the top surface.

### CROSS-REFERENCE TO RELATED APPLICATIONS

This patent application is a national phase filing under section 371 of PCT/EP2022/063009, filed May 13, 2022, which claims the priority of German patent application 102021113843.4, filed May 28, 2021, each of which is incorporated herein by reference in its entirety.

### TECHNICAL FIELD

The present invention relates to a device comprising a piezoelectric multilayer element and a mechanical amplifying element. Such a device may be used, for example, as an actuator for generating a haptically perceptible signal.

### BACKGROUND

From DE 10 2019 120 720 A1, AT 15 914 U1, DE 10 2015 117 262 A1 as well as DE 10 2016 116 763 A1, actuators with a piezoelectric element between two amplifying elements are known in each case, wherein the element changes its expansion when an electrical voltage is applied in a first direction and the amplifying elements deform as a result of the expansion of the element in such a way that a partial area is moved relative to the element in a second direction, which is essentially perpendicular to the first direction. In such actuators, a strong application of force or deformation, for example as a result of a drop or collision, may result in damage to the amplifying element or the actuator or the connection between the amplifying element and the actuator, which may result in failure of the actuator function.

DE 196 25 921 A1 shows an electrostrictive drive with an actuator consisting of piezo elements arranged in a row like a package.

WO 2014/096 565 A1 shows a device comprising a piezoelectric element and a metallic structure that generates a haptic signal.

DE 10 2004 002 249 B4 shows a piezo-active actuator with motion amplification.

U.S. Pat. No. 6,402,499 B1 shows a device in which a piezoelectric element drives a piston, with a spring system transmitting an oscillating motion of the piezoelectric element to the piston.

WO 2020/011 526 A1 shows a stylus that has a piezoelectric actuator.

DE 100 17 334 A1 shows a piezoelectric actuator with a stop device.

WO 2010/094 520 A1 concerns a piezoelectric generator, in particular for use in a vehicle tire control system.

U.S. Pat. No. 8,154,177 B1 shows a device for “energy harvesting.”

### SUMMARY

Embodiments provide an improved device in which, for example, the risk of damage is reduced.

A device is proposed comprising a piezoelectric multilayer element having an top surface configured to change its extension in a first direction in response to an applied voltage. The device comprises a mechanical amplifying element having an end portion fixed to the top surface of the piezoelectric multilayer element and an active portion movable relative to the piezoelectric multilayer element, wherein the mechanical amplifying element is configured such that that the active portion is moved in a second direction perpendicular to the first direction when the extension of the piezoelectric multilayer element changes, wherein the second direction is parallel to the surface normal of the top surface and the device comprises a mechanical stop which limits a distance by which the active portion can be moved towards the top surface.

By limiting the distance by which the active portion can be moved toward the top surface, excessive deformation of the mechanical amplifying element can be prevented. This can prevent damage to the device and reduce a risk of failure of the device. Since the mechanical stop is formed by the device itself, design provisions in a mechanical environment in which the device is installed can be omitted. This can simplify installation of the device and reduce the risk of failure of the device.

The distance by which the active portion can be moved towards the top surface can be determined in each case on the basis of a rest state of the device in which no voltage is applied to the device. The distance by which the active portion can be moved towards the top surface can, for example, be limited to a maximum of 5.0 mm. In other embodiments, the distance may be limited to less than 500 μm, preferably less than 100 μm. Preferably, the maximum distance is limited to less than 50% of the distance between the active portion and the top surface in a rest position of the device. This means that damage to the device can be ruled out in any case.

In a rest state of the device, the active portion can be spaced from the top surface by a free height. The free height can be defined as the maximum distance between a point on the active portion and a point on the top surface, the two points being opposite each other. The mechanical stop can be arranged and designed in such a way that the distance by which the active portion can be moved from the rest state towards the top surface has a length that is no more than 50% of the free height. If the distance is limited in this way, damage to the devices due to a fall or otherwise generated excessive forces can be avoided.

The mechanical stop can be arranged and designed in such a way that the distance by which the active portion can be moved from the rest state towards the top surface has a length that is more than 1% of the free height. If the distance by which the active portion can be moved from the rest state towards the top surface were to be limited to less than 1%, it might not be possible to reliably generate a haptically perceptible signal because the amplitude of the signal would be too limited.

Preferably, the mechanical stop can be arranged and designed in such a way that the distance by which the active portion can be moved from the rest state towards the top surface has a length that lies in a range between 2% and 40% of the free height. In this range, the generation of easily perceivable haptic signals is ensured and damage is reliably avoided.

The distance can be limited by the mechanical stop striking the top surface and thus preventing further movement of the active portion towards the top surface. Alternatively, the distance can be limited by the mechanical stop mounted on the piezoelectric multilayer element striking the active portion and thus preventing further movement of the active portion towards the top surface.

The mechanical stop can be formed either on the active portion or on the piezoelectric element. If the mechanical stop is formed on the active portion, it can be formed by an element attached to the active portion. The element can be bonded, screwed or welded to the active portion, for example. The element can be a support ring or a support plate, for example.

Alternatively, the mechanical stop can be formed by shaping a partial area of the active portion. The partial area can be formed by deep drawing or punching. The partial area is formed in such a way that its distance from the piezoelectric multilayer element is less than the distance from other areas of the active portion, so that when the active portion moves toward the piezoelectric multilayer element, the partial area first comes into contact with the piezoelectric multilayer element.

The mechanical stop can be formed by an element attached to the top surface of the piezoelectric multilayer element, which is bonded or screwed to the top surface, for example.

The mechanical stop can be arranged and designed in such a way that the distance by which the active portion can be moved towards the top surface is limited to a length at which damage to the device is prevented. By limiting the distance, irreversible deformation of the mechanical amplifying element can be prevented.

The piezoelectric multilayer element may have a cuboid base body with a rectangular base surface, wherein the mechanical amplifying element is bow-shaped. Alternatively, the base body may have a square base surface, wherein the mechanical amplifying element is frustoconical.

The device can be an actuator. In particular, the device can be used to generate a haptically perceptible signal. Alternatively or additionally, the device can be a sensor designed to measure a pressure exerted on the active portion of the mechanical amplification element. In particular, the device can be used simultaneously as an actuator and a sensor.

Preferred embodiments of the present invention are described below with reference to the figures.

### BRIEF DESCRIPTION OF THE DRAWINGS

FIG. 1 shows a first embodiment of the device in a side view;

FIG. 2 shows a second embodiment of the device in a side view; and

FIG. 3 shows a cross-section of a third embodiment of the device in perspective view.

### DETAILED DESCRIPTION OF ILLUSTRATIVE EMBODIMENTS

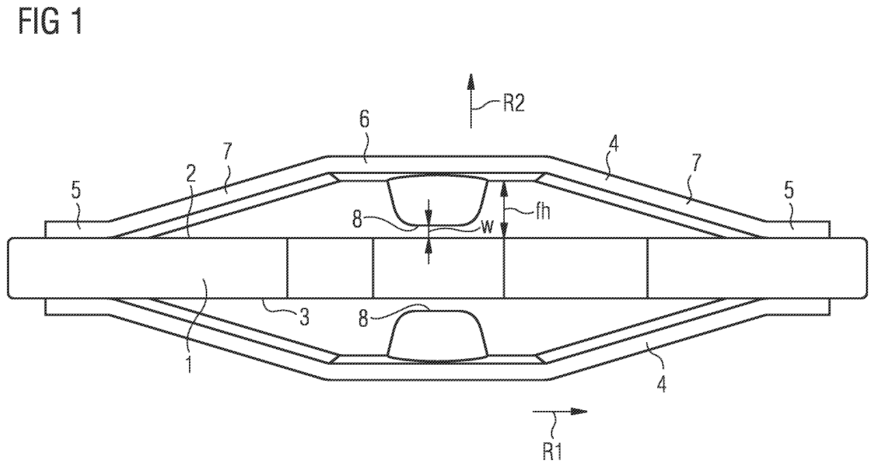

FIG. 1 shows a first embodiment of a device that can be used in particular to generate a haptically perceptible signal. Alternatively or additionally, the device can be used as a pressure sensor.

The device has a piezoelectric multilayer element 1. The piezoelectric multilayer element 1 has inner electrodes and piezoelectric layers that are alternately stacked on top of each other. The piezoelectric multilayer element 1 is cuboidal in shape. The piezoelectric multilayer element 1 has a top surface 2 and a bottom surface 3 opposite to the top surface 2.

The height is the extension of the piezoelectric multilayer element 1 between the top surface 2 and the bottom surface 3. The height of the piezoelectric multilayer element 1 can be between 0.3 mm and 20 mm, preferably between 0.5 mm and 10 mm.

The piezoelectric multilayer element 1 has a base area which is rectangular to the height and which is spanned by a width and a length. The length can be between 5 mm and 80 mm and the width can be between 2 mm and 20 mm, with the length designating the longer edge of the rectangular base surface. In the embodiment example shown in FIG. 1, the piezoelectric multilayer element 1 has a length of 12 mm, a width of 4 mm, and a height of 1.75 mm.

In the following, the first direction R1 is referred to as a longitudinal direction of the piezoelectric multilayer element 1, i.e., a direction running along the length of the piezoelectric multilayer element.

When an electric voltage is applied to the inner electrodes of the piezoelectric multilayer element, the piezoelectric multilayer element 1 deforms as a result of the piezoelectric effect, changing its extension in the first direction R1.

The device further comprises two mechanical amplifying elements 4. A first mechanical amplifying element 4 is attached to the top surface 2 of the piezoelectric multilayer element 1. A second mechanical amplifying element 4 is attached to the bottom surface 3 of the piezoelectric multilayer element 1. Since both mechanical amplification elements 4 are identical in construction, the first mechanical amplification element 4 is described below.

The first mechanical amplifying element 4 is bow-shaped. In this case, the mechanical amplifying element 4 has two opposite end portions 5, each of which is attached to the top surface 2 of the piezoelectric multilayer element 1. For example, the end portions 5 may be glued to the top surface 2 of the piezoelectric multilayer element 1.

Furthermore, the mechanical amplification element 4 has an active portion 6. The active portion 6 is movable relative to the top surface 2 of the piezoelectric multilayer element 1. If no electrical voltage is applied to the piezoelectric multilayer element 1 and the latter is accordingly in a rest state, the active portion 6 of the mechanical amplification element 4 is separated from the top surface 2 by a free height fh. In this context, the free height fh can be referred to as the maximum distance between a point on the top surface 2 and a point on the side of the mechanical amplification element 4 facing the top surface, with a connecting line of the two points being perpendicular to the top surface. The active portion 6 is parallel to the top surface 2 of the piezoelectric multilayer element 1.

Furthermore, the bow-shaped mechanical amplifying element 4 has two angular portions 7, each connecting the two end portions 5 to the active portion 6. Each of the angular portions 7 extends at a shallow angle with respect to the top surface 2 of the piezoelectric multilayer element 1. The connection points between the end portions 5 and the angular portions 7, and the connection points between the angular portions 7 and the active portion 6, respectively form hinge points at which the mechanical amplifying element can deform when the extension of the piezoelectric multilayer element 1 is changed in the first direction R1.

If the piezoelectric multilayer element 1 expands in the first direction R1, the two end portions 5 of the first mechanical amplifying element 4 are pulled apart. This movement of the end portions 5 is transmitted via the angular portion 7 to the active portion 6, which consequently moves towards the top surface 2 of the piezoelectric multilayer element 1. Conversely, if the extension of the piezoelectric multilayer element 1 in the first direction R1 is reduced, the two end portions 5 are moved towards each other, causing the active portion 6 to move away from the top surface 2 of the piezoelectric multilayer element 1.

The mechanical amplification element 4 thus makes it possible to convert a change in the extension of the piezoelectric multi-layer element 1 in the first direction R1 into a movement of the active portion 6 in a second direction R2, the second direction being perpendicular to the first direction. In this case, the amplitude of the movement in the second direction R2 can be significantly greater than the change in the extent of the piezoelectric multi-layer element in the first direction R1.

If an alternating voltage is now applied to the inner electrodes of the piezoelectric multilayer element 1, the active portion 6 is set into vibration, oscillating in the second direction R2. This vibration can generate a haptically perceptible signal.

Analogously, the device can also be used as a sensor, whereby a pressure applied to the active portion 6 of the mechanical amplification element leads to the generation of a voltage in the piezoelectric multilayer element 1.

A mechanical stop 8 is formed on the active portion 6 of the mechanical amplification element 4. If the active portion 6 is moved towards the top surface 2 of the piezoelectric multilayer element 1, the distance w by which this movement is possible is limited by the mechanical stop. The mechanical stop 8 then strikes the top surface 2 of the piezoelectric multilayer element 1 and prevents further movement of the active portion 6 towards the piezoelectric multilayer element 1.

In the embodiment shown in FIG. 1, the mechanical stop 8 is formed by reshaping a part of the active portion 6 of the bow-shaped amplifying element. The reshaping is formed by deep drawing the part of the active portion. The formed part of the active portion 6 protrudes from the rest of the active portion in the direction of the top surface 2. If the active portion 6 is now moved towards the top surface 2, the mechanical stop 8 first comes into contact with the top surface 2 and prevents further movement of the active portion 6 towards the top surface 2. This also prevents further deformation of the mechanical amplifying element 4.

In this way, the mechanical stop prevents, in particular, the mechanical amplifying element 4 from being irreversibly deformed as a result of the application of excessive force. This prevents damage to the mechanical amplifying element 4. Such an excessive force effect can occur, in particular, as a result of a fall or a collision of the device.

The mechanical stop can be designed in such a way that the active portion can be moved towards the top surface by a maximum distance of between 50 μm and 5 mm. Accordingly, the distance between the mechanical stop and the top surface can be between 50 μm and 5 mm in the rest state.

The maximum distance w by which the active portion 6 can be moved towards the top surface 2 can be less than 50% of the free height fh. In the case of a mechanical amplifying element 4 in which the maximum distance w is limited to less than 50% of the free height fh, damage due to excessive deformation of the mechanical amplifying element 4 can be ruled out.

If the mechanical stop 8 is formed by shaping a portion of the active portion 6, the shaping may be constructed to a tolerance of less than 15% accuracy, preferably to a tolerance of less than 10%.

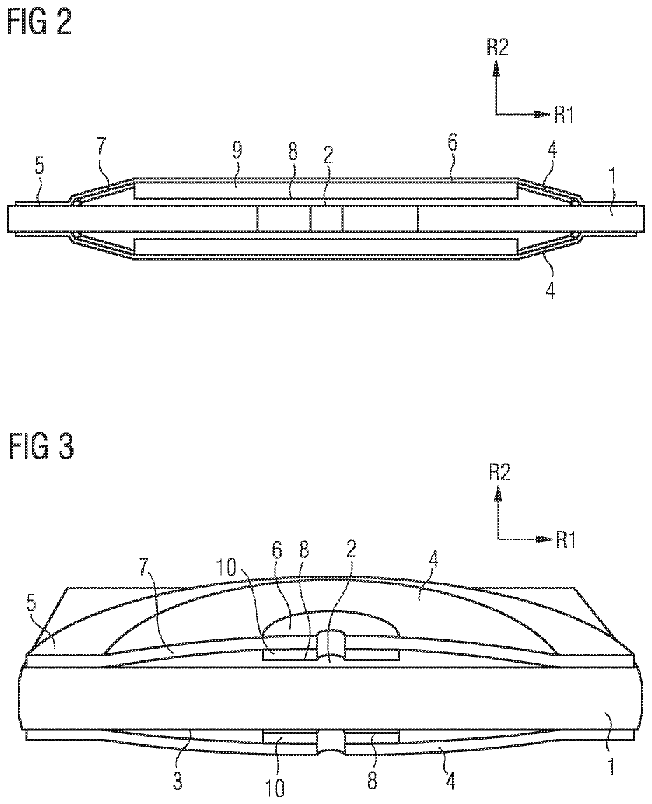

FIG. 2 shows a second embodiment of the device. In the second embodiment, the mechanical stop 8 is formed by a support plate 9 that is screwed to the active portion 6. In this case, the support plate 9 is formed on a side of the active portion 6 that faces the top surface 2 of the piezoelectric multilayer element. The support plate 9 forms the mechanical stop 8, which first comes into contact with the top surface of the piezoelectric multilayer element and limits the maximum distance w by which the active portion 6 can be moved towards the top surface 2. The piezoelectric multilayer element 1 shown in the second embodiment has a length of 60 mm, a width of 5 mm and a height of 7 mm. The active portion 6 can be moved from its rest position towards the top surface 2 of the piezoelectric multilayer element 1 by a maximum distance of 2 mm.

FIG. 3 shows a third embodiment example of the device. In the embodiment example shown in FIG. 3, the piezoelectric multilayer element 1 has a square base. FIG. 3 shows a cross-section of the device. The piezoelectric multilayer element 1 has a length and a width of 13 mm each and a height of 1.8 mm.

The mechanical amplifying elements 4 are frustoconical in shape. The truncated cone-shaped amplifying elements 4 have end portions 5 attached to the top surface 2 and the bottom surface 3 of the piezoelectric multilayer element 1, respectively. The frustoconical amplifying elements 4 each have an active portion 6 which runs parallel to the top surface and the bottom surface of the piezoelectric multilayer element, respectively, and is spaced apart from these by a free height fh in the rest state. The end portion 5 and the active portion 6 are connected via an angle region 7.

The mechanical stops 8 at the active portions 6 of the mechanical amplifying elements 4 are formed by support rings 10 which are glued to the sides of the mechanical amplifying elements 4 facing the top surface 2 and the bottom surface 3, respectively. In the rest state of the device, the mechanical stops 8 are spaced from the top surface 2 and from the bottom surface 3, respectively, by a length that is smaller than the free height fh. The active portion 6 of the mechanical amplifying element 4, which is attached to the top surface 2, can be moved from the rest state towards the top surface by a maximum distance w, which is equal to the length by which the mechanical stop 8 is spaced from the top surface 2 in the rest state. In the third embodiment, the mechanical stop 8 limits the maximum distance w by which the active portions 6 can be moved towards the top or bottom surface from the rest position to 0.2 mm.

In further embodiments not shown, the mechanical stop 8 may be formed on the piezoelectric multilayer element 1. In this case, the stop 8 can be arranged on the top surface 2 of the piezoelectric multilayer element 1, which faces the active portion, and can be formed, for example, by an element glued to the surface 2.

1-15. (canceled)

16. A device comprising:
a piezoelectric multilayer element having a top surface and being configured to change its extension in a first direction in response to an applied voltage;
a mechanical amplifying element having an end portion fixed to the top surface of the piezoelectric multilayer element and an active portion movable relative to the piezoelectric multilayer element,
wherein the mechanical amplifying element is configured such that the active portion is movable in a second direction perpendicular to the first direction when an extension of the piezoelectric multilayer element changes, the second direction being parallel to a surface normal of the top surface; and
a mechanical stop limiting a distance by which the active portion is movable towards the top surface.

17. The device according to claim 16,
wherein, in a rest state of the device, the active portion is spaced from the top surface by a free height, and
wherein the mechanical stop is configured in such a way that the distance by which the active portion is movable from the rest state towards the top surface has a length which is not more than 50% of the free height.

18. The device according to claim 16,
wherein the limitation of the distance is affected by the mechanical stop striking against the top surface thereby preventing further movement of the active portion towards the top surface, or
wherein the limitation of the distance is affected by the mechanical stop striking the piezoelectric multilayer element thereby preventing further movement of the active portion towards the top surface.

19. The device according to claim 16, wherein the mechanical stop is the active portion.

20. The device according to claim 16, wherein the mechanical stop is an element fixed to the active portion.

21. The device according to claim 20, wherein the element is bonded, screwed or welded to the active portion.

22. The device according to claim 16, wherein the mechanical stop is formed by shaping a partial area of the active portion.

23. The device according to claim 16, wherein the mechanical stop is formed by deep drawing or punching a partial area of the active portion.

24. The device according to claim 16, wherein the mechanical stop is an element fixed to the top surface of the piezoelectric multilayer element.

25. The device according to claim 24, wherein the element is bonded or screwed to the top surface of the piezoelectric multilayer element.

26. The device according to claim 16, wherein the mechanical stop is configured in such a way that the distance by which the active portion is movable towards the top surface is limited to a length at which damage to the device is prevented.

27. The device according to claim 16, wherein the mechanical stop is configured such that the distance by which the active portion is movable towards the top surface is limited to a length at which a damage of the mechanical amplifying element is prevented.

28. The device according to claim 16, wherein the mechanical stop is configured such that the distance by which the active portion is movable towards the top surface is limited to a length at which it is prevented that the mechanical amplifying element is damaged by an excessive force.

29. The device according to claim 16,
wherein the piezoelectric multilayer element has a cuboid base body with a rectangular base surface, and
wherein the mechanical amplifying element is bow-shaped.

30. The device according to claim 16,
wherein the piezoelectric multilayer element has a cuboid base body with a square base surface, and
wherein the mechanical amplifying element is frustoconical.

31. The device according to claim 16, wherein the device is an actuator.

32. The device according to claim 16, wherein the device is a sensor configured to measure a pressure exerted on the active portion of the mechanical amplification element.
